(19) United States
(12) Patent Application Publication
(10) Pub. No.: US 2026/0123178 A1
(43) Pub. Date: Apr. 30, 2026

(54) MOTHER BOARD FOR DISPLAY DEVICE AND METHOD OF MANUFACTURING THE DISPLAY DEVICE

(71) Applicant: Magnolia White Corporation, Tokyo (JP)

(72) Inventors: Naoya IWAHASHI, Tokyo (JP); Sho YANAGISAWA, Tokyo (JP); Hiroshi TABATAKE, Tokyo (JP)

(73) Assignee: Magnolia White Corporation, Tokyo (JP)

(21) Appl. No.: 19/372,325

(22) Filed: Oct. 29, 2025

(30) Foreign Application Priority Data
Oct. 29, 2024 (JP) 2024-189917

(51) Int. Cl. H10K 59/12; H10K 59/122; H10K 59/80; H10K 71/00

(52) U.S. Cl. CPC H10K 59/1201; H10K 59/122; H10K 59/871; H10K 71/851

(57) ABSTRACT

According to one embodiment, a mother board for a display device includes a display area for displaying an image, a margin area on an outer side of a cut line for cutting out the display area, an inorganic insulating layer disposed in the display area and the margin area, a display element disposed in the display area, a first partition disposed above the inorganic insulating layer in the margin area, a first sealing layer formed of an inorganic insulating material and disposed above the display element and the first partition, and a first resin layer disposed above the first sealing layer in the margin area.

### CROSS-REFERENCE TO RELATED APPLICATIONS

This application is based upon and claims the benefit of priority from Japanese Patent Application No. 2024-189917, filed Oct. 29, 2024, the entire contents of which are incorporated herein by reference.

### FIELD

Embodiments described herein relate generally to a mother board for a display device and a method of manufacturing a display device.

### BACKGROUND

In recent years, display devices in which organic light-emitting diodes (OLEDs) are applied as display elements have been put into practical use. In display devices of this type, a technology of improving yield is required.

### BRIEF DESCRIPTION OF THE DRAWINGS

FIG. 1 is a diagram showing a configuration example of a display device according to one embodiment.

FIG. 2 is a plan view schematically showing an example of layout of subpixels.

FIG. 3 is a cross-sectional view schematically showing the display panel taken along the line III-III in FIG. 2.

FIG. 4 is a plan view schematically showing a mother board according to this embodiment.

FIG. 5 is a plan view schematically showing a part of the mother board.

FIG. 6 is a cross-sectional view schematically showing a panel portion taken along the line VI-VI in FIG. 5.

FIG. 7 is an enlarged view schematically showing a VII portion in FIG. 6.

FIG. 8 is a flowchart showing an example of a method of manufacturing the display device.

FIG. 9A is a cross-sectional view schematically showing a processing step in the manufacturing of the display device.

FIG. 9B is a cross-sectional view schematically showing a processing step following that of FIG. 9A.

FIG. 9C is a cross-sectional view schematically showing a processing step following that of FIG. 9B.

FIG. 9D is a cross-sectional view schematically showing a processing step following that of FIG. 9C.

FIG. 9E is a cross-sectional view schematically showing a processing step following that of FIG. 9D.

FIG. 9F is a cross-sectional view schematically showing a processing step following that of FIG. 9E.

FIG. 9G is a cross-sectional view schematically showing a processing step following that of FIG. 9F.

FIG. 9H is a cross-sectional view schematically showing a processing step following that of FIG. 9G.

FIG. 9I is a cross-sectional view schematically showing a processing step following that of FIG. 9H.

FIG. 9J is a cross-sectional view schematically showing a processing step following that of FIG. 9I.

FIG. 10A is a cross-sectional view schematically showing an island-shaped partition and its surrounding configuration in a processing step in the manufacturing of the display device.

FIG. 10B is a cross-sectional view schematically showing a processing step following that of FIG. 10A.

FIG. 10C is a cross-sectional view schematically showing a processing step following that of FIG. 10B.

FIG. 10D is a cross-sectional view schematically showing a processing step following that of FIG. 10C.

FIG. 11A is a cross-sectional view schematically showing a terminal portion for explaining a process of forming apertures in a rib layer and sealing layer of the terminal portion.

FIG. 11B is a cross-sectional view schematically showing a processing step following that of FIG. 11A.

FIG. 11C is a cross-sectional view schematically showing a processing step following that of FIG. 11B.

FIG. 11D is a cross-sectional view schematically showing a processing step following that of FIG. 11C.

FIG. 12 is a plan view schematically showing a mother board according to a comparative example.

FIG. 13 is a plan view schematically showing a mother board according to one embodiment.

FIG. 14 is a plan view schematically showing another example of the shape of the panel body.

### DETAILED DESCRIPTION

In general, according to one embodiment, a mother board for a display device, comprises a display area for displaying an image, a margin area on an outer side of a cut line for cutting out the display area, an inorganic insulating layer disposed in the display area and the margin area, a display element disposed in the display area, a first partition disposed above the inorganic insulating layer in the margin area, a first sealing layer formed of an inorganic insulating material and disposed above the display element and the first partition, and a first resin layer disposed above the first sealing layer in the margin area.

According to another embodiment, a mother board for a display device comprises a display area which displays images, a margin area on an outer side of a first cut line for cutting out the display area, a display element disposed in the display area, a first partition arranged in the margin area, a first sealing layer formed of an inorganic insulating material and disposed above the display element and the first partition, a first resin layer disposed on the first sealing layer in the margin area, and a second resin layer disposed on the first sealing layer in the display area. The margin area includes a plurality of island-shaped portions including the first partition, the first sealing layer, and the first resin layer. The plurality of island-shaped portions are each disposed, in plan view, to be separated from the second resin layer around the first cut line.

According to still another embodiment, a method of manufacturing a display device, comprises: preparing a substrate including a display area which displays images and a margin area on an outer side of a first cut line for cutting out the display area, forming an inorganic insulating layer on the display area and the margin area, forming a first partition including a lower portion and an upper portion including an end portion protruding from a side surface of the lower portion, on the inorganic insulating layer in the margin area, forming a display element in the display area, forming a first sealing layer above the display element and the first partition, and forming a first resin layer on the first sealing layer in the margin area.

With configurations such as described above, it is possible to provide a mother board for display device and a method of manufacturing a display device, which can improve the yield.

An embodiment will now be described hereinafter with reference to the accompanying drawings. Note that the disclosure is merely an example, and proper changes within the spirit of the invention, which are easily conceivable by a skilled person, are included in the scope of the invention as a matter of course.

In addition, as to the drawings, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

Note that, in order to make the descriptions more easily understandable, some of the drawings illustrate an X axis, a Y axis and a Z axis orthogonal to each other. A direction along the X axis is referred to as a first direction X, a direction along the Y axis is referred to as a second direction Y and a direction along the Z axis is referred to as a third direction Z. Further, viewing the constitutional elements parallel to the Z direction is referred to as plan view.

The display device according to each embodiment is an organic electroluminescence display device comprising organic light-emitting diodes (OLEDs) as display elements, and may be incorporated into various electronic devices such as televisions, personal computers, in-vehicle devices, tablet terminals, smartphones, mobile phone terminals, wearable devices and the like.

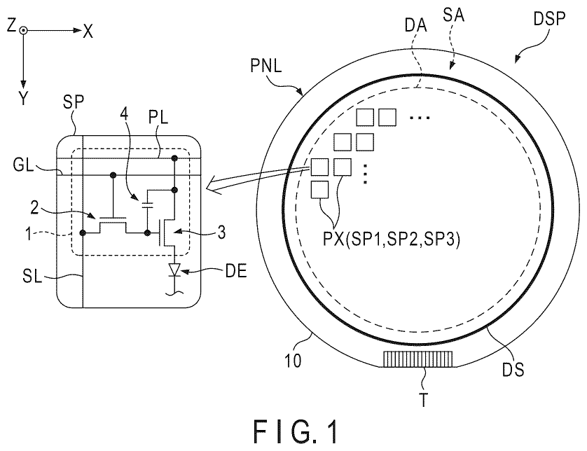

FIG. 1 is a diagram showing a configuration example of a display device DSP according to this embodiment. The display device DSP comprises a display panel PNL including an insulating substrate 10. The display panel PNL comprises a display area DA that displays images and a peripheral area SA that surrounds the display area DA. The substrate 10 may be formed, for example, of glass or resin film having plasticity.

In this embodiment, the shape of the substrate 10 and the display area DA in plan view is circular. Here, the term “circular” is not limited to a perfect circle, but may include shapes such as a circular shape a part of which is missing, an elliptical shape, or an oblong elliptical shape.

Further, the shape of the substrate 10 and the display area DA in plan view is not limited to a circular shape, but may as well be some other shape such as rectangular, square, or elliptical.

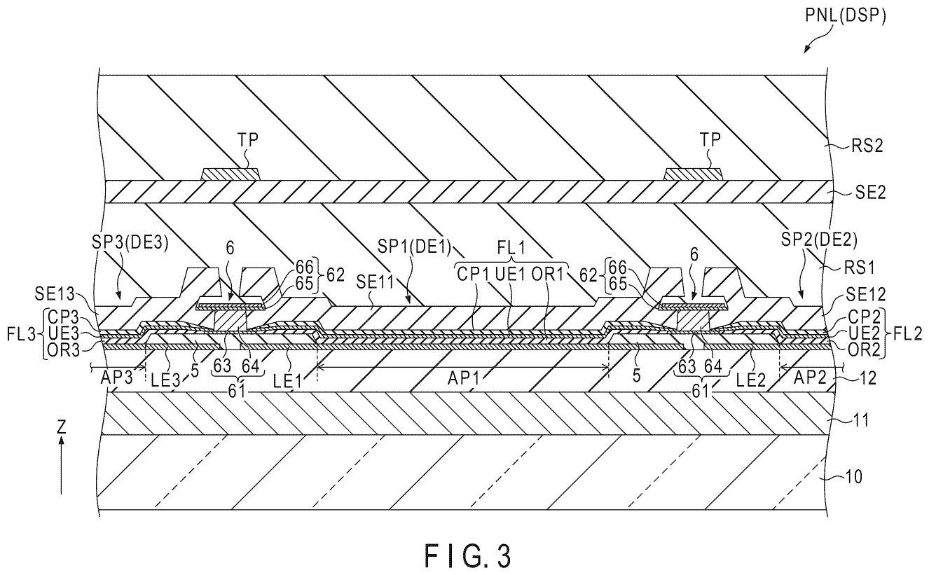

In an example of FIG. 1, a ring-shaped dam structure DS is disposed on the peripheral area SA. The dam structure DS surrounds the display area DA. The shape of the dam structure DS in plan view is, for example, circular, but is not limited to that of this example. The dam structure DS can be formed, for example, from an organic insulating layer 12, which will be described later (see FIG. 3).

The display area DA comprises a plurality of pixels PX arranged in a matrix along the first direction X and the second direction Y. Each of the pixels PX contains a plurality of subpixels SP that display different colors. This embodiment is assumed that each of the pixels PX contains a subpixel SP1 of a first color, a subpixel SP2 of a second color, and a subpixel SP3 of a third color. For example, the first color is blue, the second color is green, and the third color is red, but the color combination is not limited to that of this example. Note that the pixels PX may each contain a subpixel of some other color such as white in addition to the above-listed subpixels SP1, SP2, and SP3 or in place of any of subpixels SP1, SP2, and SP3.

The display device DSP further comprises a terminal portion T disposed in the peripheral area SA. The terminal portion T is connected to a flexible circuit board that supplies voltage or signals for driving the display device DSP, for example.

The subpixels SP each comprises a pixel circuit 1 and a display element DE driven by the pixel circuit 1. The pixel circuit 1 comprises a pixel switch 2, a drive transistor 3, and a capacitor 4. The pixel switch 2 and drive transistor 3 are switching elements formed, for example, from thin-film transistors.

The display area DA has a plurality of scanning lines GL that supply scanning signals to the pixel circuits 1 of the respective subpixels SP, a plurality of signal lines SL that supply image signals to the pixel circuits 1 of the respective subpixels SP, and a plurality of power lines PL. In the example shown in FIG. 1, the scanning lines GL and power lines PL extend along the first direction X, and the signal lines SL extend along the second direction Y.

The gate electrode of the pixel switch 2 is connected to a respective one of the scanning lines GL. One of the source electrode and drain electrode of the pixel switch 2 is connected to the respective one of the signal line SL, and the other is connected to the gate electrode of the drive transistor 3 and the capacitor 4. In the drive transistor 3, one of the source electrode and drain electrode is connected to the respective one of the power lines PL and the capacitor 4, and the other is connected to the display element DE.

Note that the configuration of the pixel circuit 1 is not limited to that of the example illustrated. For example, the pixel circuit 1 may comprise more thin-film transistors and capacitors.

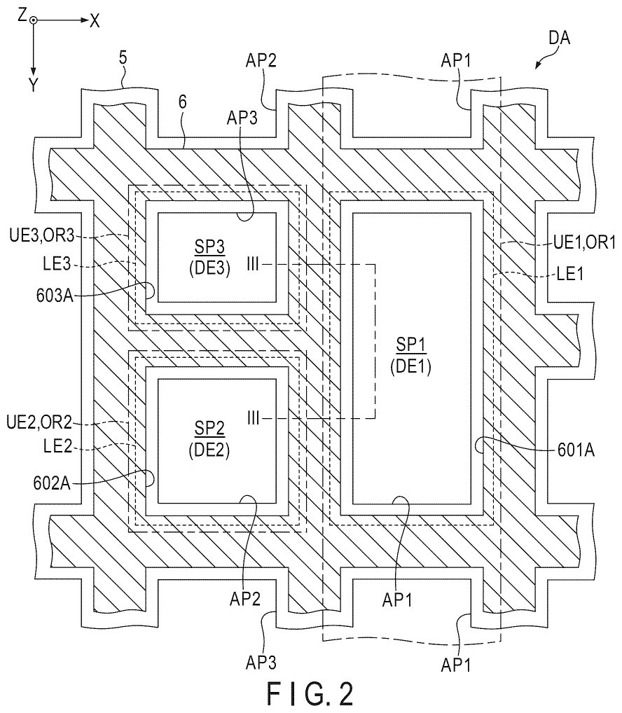

FIG. 2 is a plan view schematically showing an example of layout of the subpixels SP1, SP2, and SP3. In the example of FIG. 2, the subpixels SP2 and SP3 are each arranged by the subpixel SP1 along the first direction X. Further, the subpixel SP2 and subpixel SP3 are arranged along the second direction Y.

When the subpixels SP1, SP2, and SP3 are arranged in such a layout, columns in each of which subpixels SP2 and SP3 are alternately arranged along the second direction Y, and columns in each of which a plurality of subpixels SP1 are repeatedly arranged along the second direction Y are formed in the display area DA. These columns are arranged alternately along the first direction X. Note that the layout of the subpixels SP1, SP2, and SP3 is not limited to that of the example shown in FIG. 2.

In the display area DA, a rib layer 5 is disposed. In this embodiment, the rib layer 5 is an example of the inorganic insulating layer. The rib layer 5 has pixel apertures AP1, AP2, and AP3 corresponding to the subpixels SP1, SP2, and SP3, respectively. In the example shown in FIG. 2, the pixel aperture AP1 is greater in size than the pixel aperture AP2, and the pixel aperture AP2 is greater in size than the pixel aperture AP3. That is, among the subpixels SP1, SP2, and SP3, the subpixels SP1 have the largest aperture ratio, and the subpixels SP3 have the smallest aperture ratio. Note here that the sizes of the pixel apertures AP1, AP2, and AP3 are not limited to those mentioned in this example.

The subpixels SP1 each comprise a lower electrode LE1, an upper electrode UE1, and an organic layer OR1, each overlapping the respective pixel aperture AP1.

The subpixels SP2 each comprise a lower electrode LE2, an upper electrode UE2, and an organic layer OR2, each overlapping the respective pixel aperture AP2. The subpixel SP3 each comprise a lower electrode LE3, an upper electrode UE3, and an organic layer OR3, each overlapping the pixel aperture AP3.

The portions of the lower electrode LE1, upper electrode UE1, and organic layer OR1, which overlap with the pixel aperture AP1 constitute the display element DE1 of the subpixel SP1. The portions of the lower electrode LE2, upper electrode UE2, and organic layer OR2, which overlap with the pixel aperture AP2 constitute the display element DE2 of the subpixel SP2. The portions of the lower electrode LE3, upper electrode UE3, and organic layer OR3, which overlap with the pixel aperture AP3 constitute the display element DE3 of the subpixel SP3. The display elements DE1, DE2, and DE3 each may further include a cap layer, which will be described later. The rib layer 5 surrounds each of the display elements DE1, DE2, and DE3.

Above the rib layer 5, a conductive partition 6 (second partition) is disposed. The partition 6 serves as wiring for supplying a common voltage to the upper electrodes UE1, UE2, and UE3. The partition 6 overlaps the rib layer 5 entirely and has a planar shape similar to that of the rib layer 5.

Specifically, the partition 6 has a partition aperture 601A in each of the subpixels SP1, a partition aperture 602A in each of the subpixels SP2, and a partition aperture 603A in each of the subpixels SP3.

The partition apertures 601A, 602A, and 603A entirely overlap the pixel apertures AP1, AP2, and AP3, respectively. Further, the partition apertures 601A, 602A, and 603A entirely overlap the display elements DE1, DE2, and DE3, respectively. That is, the partition 6 surrounds the display elements DE1, DE2, and DE3.

FIG. 3 is a cross-sectional view schematically showing the display panel PNL taken along the line III-III in FIG. 2. On the substrate 10 described above, a circuit layer 11 is disposed. The circuit layer 11 includes various circuits and wiring lines such as the pixel circuit 1, scanning lines GL, signal lines SL, and power lines PL shown in FIG. 1. The circuit layer 11 is covered by an organic insulating layer 12. The organic insulating layer 12 functions as a planarization film to planarize the unevenness caused by the circuit layer 11.

The lower electrodes LE1, LE2, and LE3 are disposed on the organic insulating layer 12. The rib layer 5 is disposed on the organic insulating layer 12 and the lower electrodes LE1, LE2, and LE3. End portions of the lower electrodes LE1, LE2, and LE3 are covered by the rib layer 5. Although not shown in the cross-sectional view of FIG. 3, the lower electrodes LE1, LE2, and LE3 are connected to the pixel circuit 1 of the circuit layer 11 through contact holes each made in the organic insulating layer 12.

The partition 6 includes a conductive lower portion 61 disposed on the rib layer 5 and an upper portion 62 disposed on the lower portion 61. In this embodiment, the lower portion 61 of the partition 6 corresponds to the second lower portion, and the upper portion 62 of the partition 6 corresponds to the second upper portion.

The upper portion 62 has a width greater than that of the lower portion 61. With this configuration, both ends of the upper portion 62 protrude beyond the respective side surfaces of the lower portion 61. Such a shape of the partition 6 is referred to as an overhanging shape.

In the example of FIG. 3, the lower portion 61 includes a bottom layer 63 disposed on the rib layer 5 and an axis layer 64 disposed on the bottom layer 63. For example, the bottom layer 63 is formed thinner than the axis layer 64. Further, in the example of FIG. 3, both end portions of the bottom layer 63 protrude from the respective side surfaces of the axis layer 64.

Furthermore, in the example shown in FIG. 3, the upper portion 62 comprises a first top layer 65 and a second top layer 66 disposed on the first top layer 65. For example, the width of the second top layer 66 is slightly less than the width of the first top layer 65. But the configuration is not limited to this, and the first top layer 65 and the second top layer 66 may have widths similar to each other.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 are in contact with the side surfaces of the lower portion 61 of the partition 6.

The display element DE1 includes a cap layer CP1 disposed on the upper electrode UE1. The display element DE2 includes a cap layer CP2 disposed on the upper electrode UE2. The display element DE3 includes a cap layer CP3 disposed on upper electrode UE3. The cap layers CP1, CP2, and CP3 serve as optical adjustment layers to improve the light extraction efficiency of the light emitted from the organic layers OR1, OR2, and OR3, respectively.

In the following description, the stacked multilayer body comprising the organic layer OR1, the upper electrode UE1, and the cap layer CP1 is referred to as a stacked multilayer film FL1, the multilayer structure comprising the organic layer OR2, the upper electrode UE2, and the cap layer CP2 is referred to as a stacked multilayer film FL2, and the multilayer structure comprising the organic layer OR3, the upper electrode UE3, and the cap layer CP3 is referred to as a stacked multilayer film FL3.

The subpixels SP1, SP2, and SP3 are provided with sealing layers SE11, SE12, and SE13, respectively. The sealing layer SE11 continuously covers the partition 6 surrounding the stacked multilayer film FL1 and the subpixels SP1. The sealing layer SE12 continuously covers the partition 6 surrounding the stacked multilayer film FL2 and the subpixels SP2. The sealing layer SE13 continuously covers the partition 6 surrounding the stacked multilayer film FL3 and the subpixels SP3.

In the example shown in FIG. 3, the sealing layer SE11 on the partition 6 between the subpixels SP1 and SP2 is spaced apart from the sealing layer SE12 on the same partition 6. Further, the sealing layer SE11 on the partition 6 between the subpixels SP1 and SP3 is spaced apart from the sealing layer SE13 on the same partition 6. Note here that any two of the sealing layers SE11, SE12, and SE13 may come into contact with the partition 6 thereabove.

For example, gaps are formed between the sealing layers SE11, SE12, and SE13 and the upper portion 62 of the partition 6. The stacked multilayer films FL1, FL2, and FL3 may be disposed in at least a part of these gaps.

The sealing layers SE11, SE12, and SE13 are covered by the resin layer RS1. The resin layer RS1 is covered by the sealing layer SE2. The sealing layer SE2 is covered by the resin layer RS2. The resin layers RS1 and RS2, and the sealing layer SE2 are continuously provided over at least the entire display area DA and a part thereof reaches the peripheral area SA.

In the example shown in FIG. 3, touch panel electrodes TP are disposed on the sealing layer SE2. The touch panel electrodes TP are covered by the resin layer RS2. The touch panel electrodes TP may be formed from metal wiring lines. The wiring lines may face the partition 6 along the third direction Z. Further, the wiring lines may have a planar shape similar to that of the partition 6.

Cover members such as a polarizer, protective film, or cover glass may be further disposed above the resin layer RS2. Such cover members may be adhered to the resin layer RS2 via an adhesive layer such as an optical clear adhesive (OCA).

The organic insulating layer 12 is formed from an organic insulating material such as polyimide. The rib layer 5 and the sealing layers SE11, SE12, SE13, and SE2 are formed from inorganic insulating materials such as silicon nitride (SiNx), silicon oxide (SiOx), and silicon nitroxide (SiON), respectively. In one example, the rib layer 5 is formed of silicon nitride, and the sealing layers SE11, SE12, SE13, and SE2 are formed of silicon nitride. The resin layers RS1 and RS2 are formed, for example, of resin materials (organic insulating materials) such as epoxy resin and acrylic resin.

The lower electrodes LE1, LE2, and LE3 each include a reflective layer formed, for example, of silver, and a pair of conductive oxide layers which respectively cover the upper and lower surfaces of the reflective layer. Each of the conductive oxide layer can be formed, for example, of a transparent conductive oxide such as indium tin oxide (ITO), indium zinc oxide (IZO), or indium gallium zinc oxide (IGZO).

The upper electrodes UE1, UE2, and UE3 are formed, for example, from a metallic material such as magnesium-silver alloy (MgAg). For example, the lower electrodes LE1, LE2, and LE3 correspond to the anode, and the upper electrodes UE1, UE2, and UE3 correspond to the cathode.

The organic layers OR1, OR2, and OR3 are each constituted by a plurality of thin films including a light-emitting layer. For example, the organic layers OR1, OR2, and OR3 have a configuration in which a hole injection layer, a hole transport layer, an electron blocking layer, an emitting layer, a hole blocking layer, an electron transport layer, and an electron injection layer are stacked in this order along the third direction Z. Note here that the organic layers OR1, OR2, and OR3 may have some other structure, such as the so-called tandem structure including a plurality of light-emitting layers.

The cap layers CP1, CP2, and CP3 have a stacked structure in which a plurality of transparent layers are stacked. These transparent layers may include layers formed from inorganic materials and layers formed from organic materials. Further, these transparent layers have refractive indices different from each other. For example, the refractive indices of these transparent layers are different from the refractive indices of the upper electrodes UE1, UE2, and UE3 and those of the sealing layers SE11, SE12, and SE13. Note that at least one of the cap layers CP1, CP2, CP3 may be omitted.

The bottom layer 63 and the axis layer 64 of the partition 6 are formed from a metal material. As the metal material for the bottom layer 63, for example, molybdenum, titanium, titanium nitride (TiN), molybdenum-tungsten alloy (MoW), or molybdenum-niobium alloy (MoNb) can be used. As the metal material of the axis layer 64, for example, aluminum, aluminum-neodymium alloy (AlNd), aluminum-yttrium alloy (AlY), or aluminum-silicon alloy (AlSi) may be used. Note that the axis layer 64 may as well be formed from an insulating material.

The first top layer 65 of the partition 6 is formed, for example, from a metal material. Further, the second top layer 66 of the partition 6 is formed, for example, from a conductive oxide. As the metal material for forming the first top layer 65, for example, titanium, titanium nitride, molybdenum, tungsten, molybdenum-tungsten alloy, or molybdenum-niobium alloy can be used. As the conductive oxide for forming the second top layer 66, for example, ITO or IZO may be used. Note that the upper portion 62 may include three or more layers or may be formed as a single layer. Further, the upper portion 62 may include a layer formed from an insulating material.

To the partition 6, a common voltage is supplied. The common voltage is supplied to each of the upper electrodes UE1, UE2, and UE3, which are in contact with the side surface of the lower portion 61. To the lower electrodes LE1, LE2, and LE3, pixel voltages corresponding to the video signals of the signal lines SL are supplied through the pixel circuits 1 of the subpixels SP1, SP2, and SP3, respectively.

The organic layers OR1, OR2, and OR3 emit light in response to the applied voltage.

Specifically, when a potential difference is created between the lower electrode LE1 and the upper electrode UE1, the light-emitting layer of the organic layer OR1 emits light of the wavelength band of the first color. When a potential difference is created between the lower electrode LE2 and the upper electrode UE2, the light-emitting layer of the organic layer OR2 emits light of the wavelength band of the second color. When a potential difference is created between the lower electrode LE3 and the upper electrode UE3, the light-emitting layer of the organic layer OR3 emits light of the wavelength band of the third color.

During the manufacturing of the display device DSP, a large-scale mother board having a number of areas each corresponding to each respective display panel PNL is fabricated. The configuration applicable to this mother board will now be described.

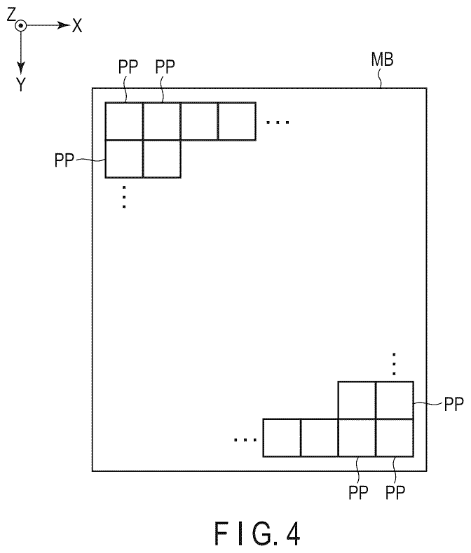

FIG. 4 is a plan view schematically showing a mother board MB (mother board for display devices) according to this embodiment. The mother board MB is, for example, rectangular as shown therein, but may have some other shape such as circular.

The mother board MB has a plurality of panel portions PP arranged in a matrix pattern. In the example of FIG. 4, a plurality of panel portions PP are arranged consecutively along the first direction X and the second direction Y. Note that the arrangement of the panel portions PP in the mother board MB is not limited to that of this example.

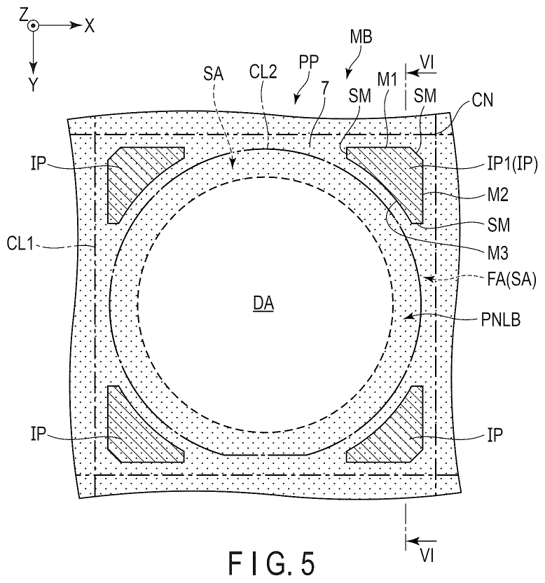

FIG. 5 is a plan view schematically showing a part of the mother board MB. In FIG. 5, one of the panel portions PP shown in FIG. 4 is focused on.

The shape of the panel portion PP in plan view is square in the example shown in FIG. 5. Note that the shape of the panel portion PP in plan view may be a rectangular shape elongated along the first direction X or a rectangular shape elongated along the second direction Y. Further, the shape of the panel portion PP in plan view may include a plurality of straight portions or curved portions.

The outer shape of each panel portion PP corresponds to a cut line CL1 (second cut line) for cutting out each panel portion PP from the mother board MB. The cut line CL1 is formed in a grid pattern. When focusing on one panel portion PP, it can be seen that the cut line CL1 is formed into a square shape.

Further, the panel portion PP has a cut line CL2 (first cut line) formed therein. The cut line CL2 corresponds to the outer shape of the display panel PNL shown in FIG. 1. The cut line CL2 is formed into a circular shape. The cut line CL2 corresponds to a cut line for cutting out the display area DA and part of the peripheral area SA from the panel portion PP. Hereinafter, the area on an inner side of the cut line CL2 may be referred to as a panel body PNLB.

The panel portion PP has the above-described display area DA and peripheral area SA. The peripheral area SA includes a margin area FA on an outer side of the cut line CL2. The margin area FA corresponds to the area between the cut line CL1 and cut line CL2, for example. The cut line CL1 corresponds to the cut line for cutting out the display area DA and the margin area FA from the mother board MB.

By the cut line CL2, the panel portion PP is divided into a part including the display area DA and a part including the margin area FA. Between the cut line CL1 and cut line CL2, a plurality of inspection pads (not shown) for inspecting the operation of the display panel PNL are disposed.

In this embodiment, a partition 7 (first partition) is disposed in the peripheral area SA including the margin area FA. In FIG. 5, the area where the partition 7 may be disposed is marked with dots. The partition 7 may be disposed in the area between the display area DA and the cut line CL2, the margin area FA, or the like. Note that the partition 7 may not be disposed in at least one of these areas. Further, the location of disposition and planar shape of the partition 7 in these areas may be appropriately determined.

From the viewpoint of efficiently cutting out the panel portion PP, it is preferable that the partition 7 should not be provided on the cut line CL1. Similarly, it is preferable that partition 7 should not be provided on the cut line CL2.

The margin area FA includes a plurality of island-shaped portions IP. Specifically, the island-shaped portions IP are disposed around the cut line CL2 in plan view. More specifically, the island-shaped portions IP are disposed between the cut line CL1 and cut line CL2 in plan view. Further, the island-shaped portions IP are disposed away from the cut line CL2.

In the example shown in FIG. 5, each of the island-shaped portions IP is arranged at a respective corner portion CN of the cut line CL1. Each of the corner portions CN is formed by a linear portion extending along the first direction X and a linear portion extending along the second direction Y of the cut line CL1. In FIG. 5, to each of the island-shaped portions IP, a slash line pattern is added.

In this embodiment, four island-shaped portions IP are disposed for one panel portion PP. The number and position of the island-shaped portions IP disposed for one panel portion PP may be appropriately changed according to the shape of the panel body PNLB.

The island-shaped portions IP each protrude in the third direction Z further than the portions other than the island-shaped portions IP in the margin area FA. In other words, the island-shaped portions IP have a thickness greater than that of the portions other than the island-shaped portions IP in the margin area FA. The island-shaped portions IP are each formed by stacking a plurality of layers (for example, the sealing layers SE1x, SE2, the resin layer RS3, and the like, which will be described later) above the partition 7.

Each of the island-shaped portions IP has a similar shape centered on the display area DA, for example. Here, focusing on one island-shaped portion IP (the island-shaped portion IP1 in FIG. 5), the shape of the island-shaped portion IP in plan view will be described.

The island-shaped portion IP 1 has edges M1, M2, and M3. In other words, the island-shaped portion IP 1 has side surfaces including the edges M1, M2, and M3, respectively. The side surfaces extend upward from the substrate 10. The edge M1 extends along the first direction X. The edge M2 extends along the second direction Y. The length of the edge M1 is approximately equal to the length of the edge M2, for example.

The edge M3 extends in a different direction from the first direction X and the second direction Y. Specifically, the edge M3 is formed along the cut line CL2. Note that the edge M3 may be formed into a curved shape or in a straight shape.

These edges M1, M2, and M3 are connected to each other by short edges SM that are shorter than the edges M1, M2, and M3. Note that the edges M1, M2, and M3 may be directly connected to each other. Further, the shape of the island-shaped portion IP1 in plan view is not limited to that of the example shown in FIG. 5.

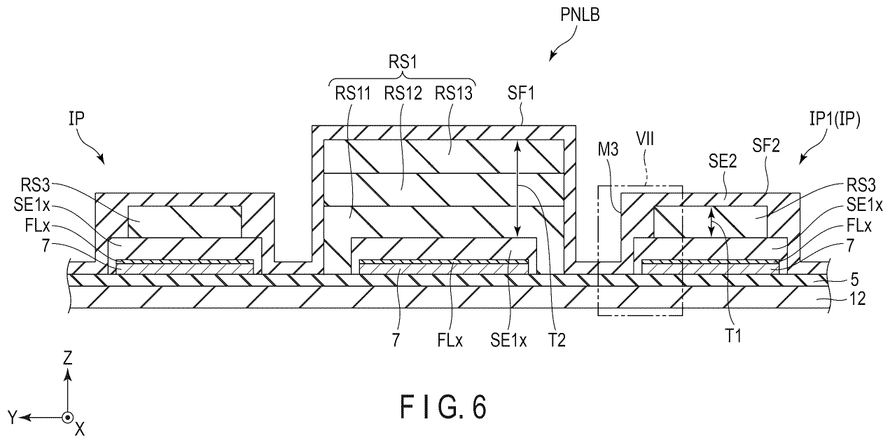

FIG. 6 is a cross-sectional view schematically showing the panel portion PP taken along the line VI-VI in FIG. 5. In FIG. 6, the panel portion PP is viewed in the direction opposite to the first direction X. The panel body PNLB in FIG. 6 indicates the peripheral area SA.

The organic insulating layer 12 and the rib layer 5 described above are formed in the peripheral area SA including the margin area FA, as well. In FIG. 6, elements below the organic insulating layer 12 are omitted.

The partition 7 is disposed on the rib layer 5. On the partition 7, a stacked multilayer film FLx is disposed. The stacked multilayer film FLx is formed by the same process and from the same material as those of one of the stacked multilayer films FL1, FL2, and FL3 shown in FIG. 3. In other words, the stacked multilayer film FLx is constituted by the same layer as one of the stacked multilayer films FL1, FL2, and FL3. The stacked multilayer film FLx is formed by the same process and from the same material as those of, for example, the stacked multilayer film FL3. Therefore, the cap layer CP3 is disposed in the margin area FA.

On the stacked multilayer film FLx, a sealing layer SE1x is disposed. The sealing layer SE1x is formed by the same process and of the same material as those of one of the sealing layers SE11, SE12, and SE13 shown in FIG. 3. The sealing layer SE1x is, for example, formed by the same process and of the same material as those of the sealing layer SE13. In this embodiment, the sealing layers SE11, SE12, SE13, and SE1x correspond to the first sealing layer.

On the sealing layer SE1x, a resin layer is disposed. The sealing layer SE1x and the resin layer are each covered by the sealing layer SE2 (the second sealing layer). Note that some other layer (for example, an overcoat layer) may be formed above the sealing layer SE2 of the panel body PNLB.

Here, the resin layer disposed above the sealing layer SE1x will be described.

First, focusing on the panel body PNLB, the resin layer RS1 shown in FIG. 3 is disposed on the sealing layer SE1x. In this embodiment, the resin layer RS1 corresponds to the second resin layer.

The resin layer RS1 is formed, for example, of a plurality of layers. The resin layer RS1 includes resin layers RS11, RS12, and RS13. The resin layers RS11, RS12, and RS13 are stacked in this order along the third direction Z. FIG. 6 discloses an example in which the resin layer RS1 is formed of three layers, but the resin layer RS1 may be formed of two or less layers or of four or more layers.

Next, focusing on the island-shaped portion IP, the resin layer RS3 (first resin layer) is formed on the sealing layer SE1x. The resin layer RS3 is formed from a single layer. The resin layer RS3 is formed by the same process and of the same material as those of the resin layer RS11 of the panel body PNLB. The island-shaped portion IP includes the partition 7, the stacked multilayer film FLx, the sealing layer SE1x, the resin layer RS3, and the sealing layer SE2.

The thickness T1 of the resin layer RS3 (shown in FIG. 6) is less than the thickness T2 of the resin layer RS1 (shown in FIG. 6). That is, the resin layer RS3 is thinner than the resin layer RS1. Here, the thickness corresponds to the distance from the upper surface of the sealing layer SE1x to the lower surface of the sealing layer SE2 taken along the third direction Z.

From another perspective, of the sealing layer SE2, the upper surface SF1 of the panel body PNLB is located above the upper surface SF2 of the island-shaped portion IP. Further, the upper surface SF2 is located above the upper surface of the sealing layer SE2 disposed in the area other than the island-shaped portion IP.

Further, the island-shaped portion IP (resin layer RS3) is separated from the resin layer RS1. In other words, the resin layer RS3 is disconnected from the resin layer RS1.

Due to the difference in thickness between the resin layers located in the island-shaped portion IP and the panel body PNLB, the island-shaped portion IP and the panel body PNLB are made to have a difference in thickness. In one example, the thicknesses of the resin layers RS11, RS12, RS13, and RS3 are each approximately 5 μm, the thickness of the sealing layer SE1x is approximately 2.2 μm, and the thickness of the sealing layer SE2 is approximately 1 μm.

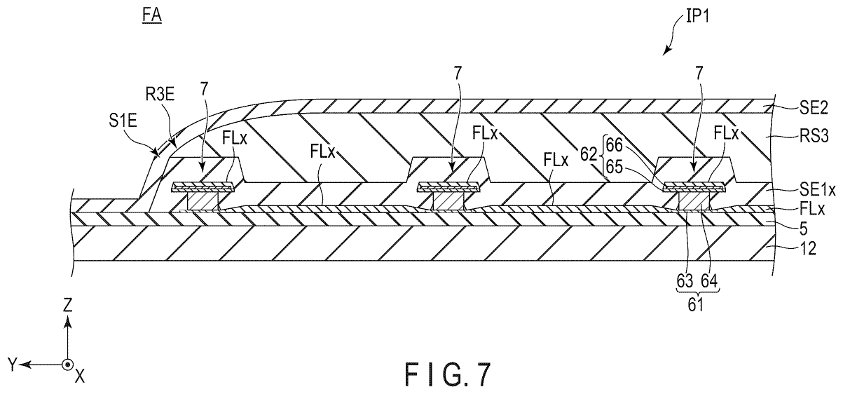

FIG. 7 is a schematic enlarged view of the VII portion shown in FIG. 6. In FIG. 7, the vicinity of the edge M3 of the island-shaped portion IP1 (the end portion of the island-shaped portion IP) is illustrated. The partition 7, as in the case of the partition 6, includes a lower portion 61 and an upper portion 62. In this embodiment, the lower portion 61 of the partition 7 corresponds to the first lower portion, and the upper portion 62 of the partition 7 corresponds to the first upper portion. The upper portion 62 has a width greater than that of the lower portion 61. The lower portion 61 of the partition 7, as in the case of the partition 6, includes a bottom layer 63 and an axis layer 64. As in the case of the partition 6, the upper portion 62 of the partition 7 includes a first top layer 65 and a second top layer 66.

The bottom layer 63, the axis layer 64, the first top layer 65, and the second top layer 66 of the partition 7 are formed from the same materials as those of the bottom layer 63, axis layer 64, first top layer 65, and second top layer 66 of the partition 6, respectively.

The stacked multilayer film FLx covers both the rib layer 5 and the partition 7. Specifically, the stacked multilayer film FLx is disposed on the upper portion 62 of the partition 7 and on the rib layer 5 between adjacent portions of the partition 7. The sealing layer SE1x continuously covers each divided portion of the stacked multilayer film FLx and the partition 7. Focusing on the partition 7, the sealing layer SE1x is in contact with the lower portion 61 and upper portion 62 of the partition 7. With this configuration, the partition 7 is not exposed from the sealing layer SE1x.

As described above, on the sealing layer SE1x, a resin layer RS3 and a sealing layer SE2 are disposed. Focusing on the end S1E of the sealing layer SE1x, the end R3E of the resin layer RS3 is located on the end S1E of the sealing layer SE1x.

In other words, the resin layer RS3 is not protruding from the end S1E of the sealing layer SE1x. From another perspective, a part of the sealing layer SE1x is not covered by the resin layer RS3, but is covered by the sealing layer SE2.

Note that the position of the end R3E of the resin layer RS3 is not limited to that of the example shown in FIG. 7. The end R3E may, for example, be located on an inner side of the island-shaped portion IP1 than that of the case shown in the example of FIG. 7. Further, the end R3E is located above the partition 7, but it may not as well be located above the partition 7.

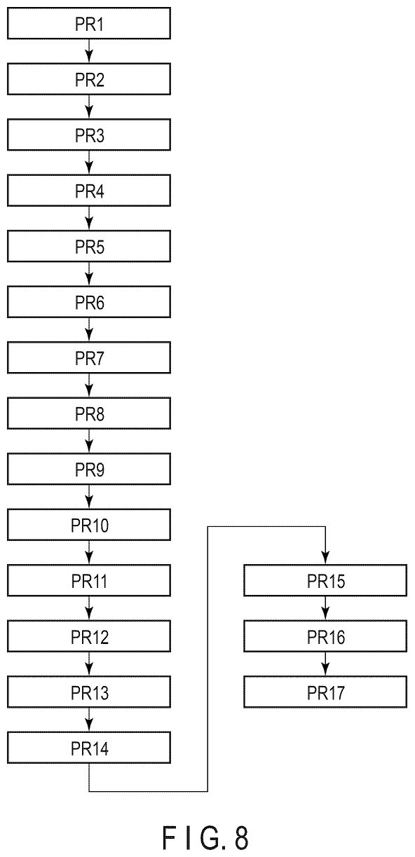

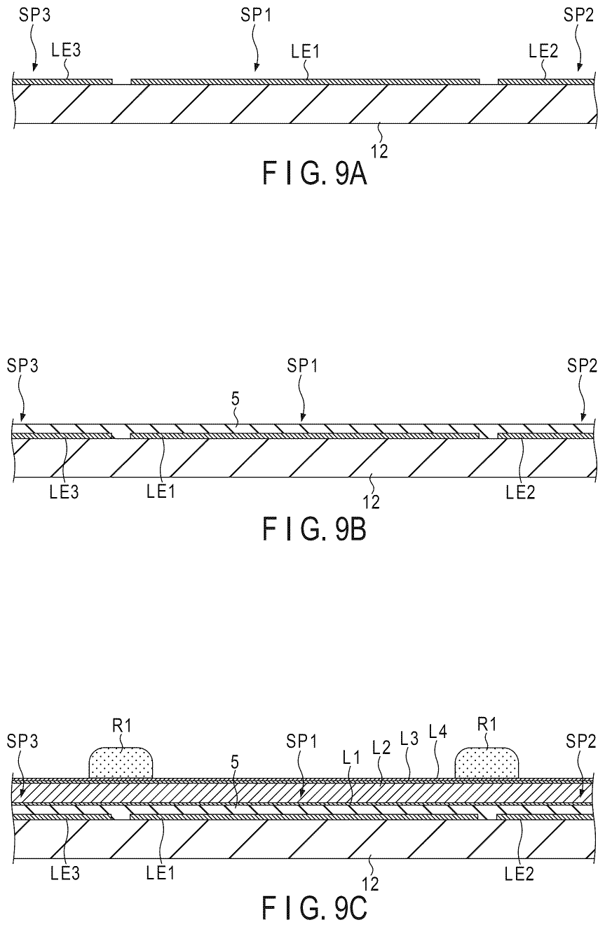

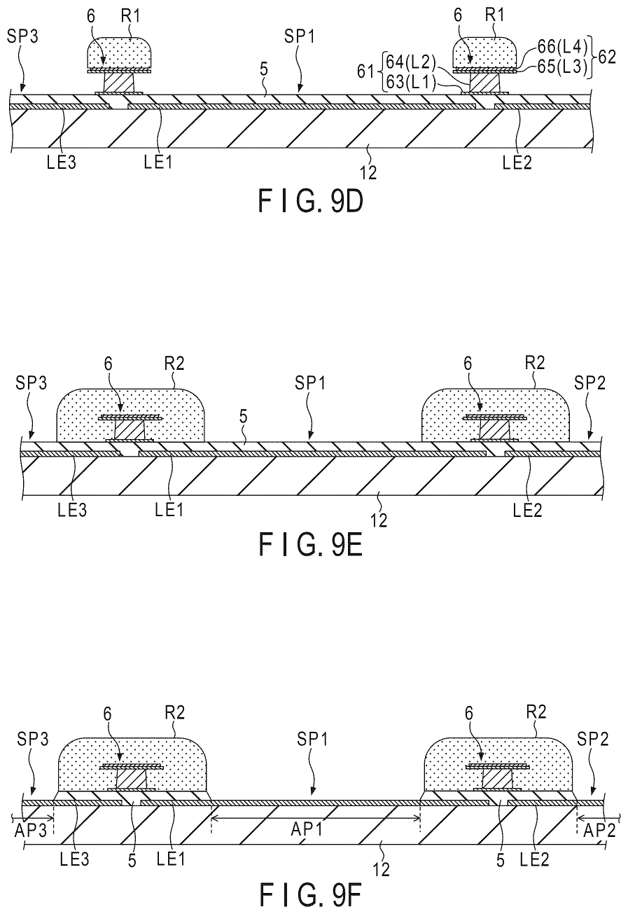

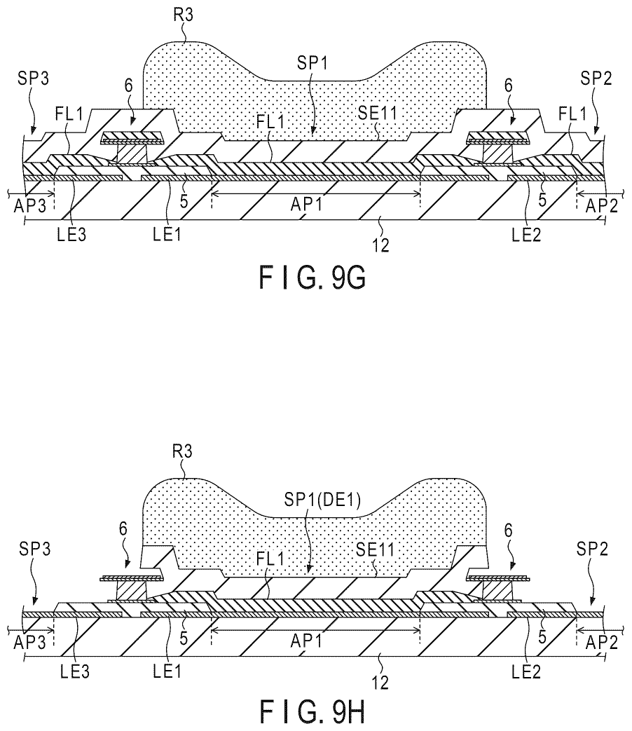

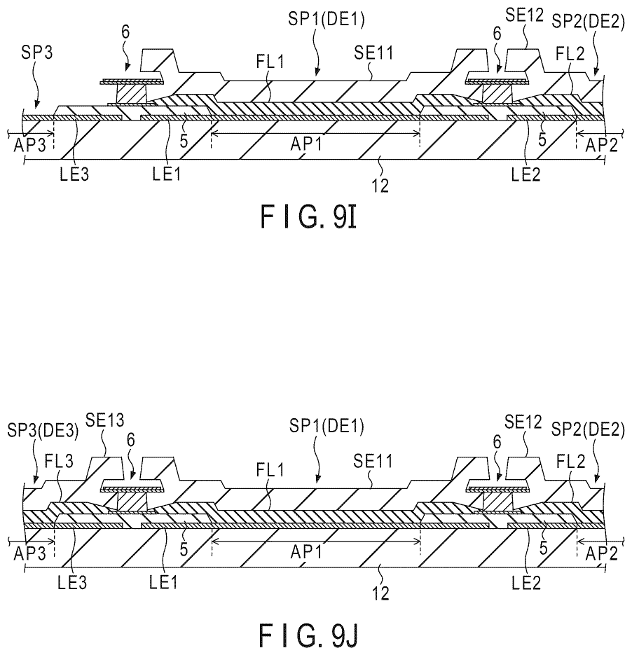

Next, an example of a method of manufacturing the display device DSP will be described. FIG. 8 is a flowchart showing an example of the method of manufacturing the display device DSP. FIGS. 9A to 9J are schematic cross-sectional views showing the method of manufacturing the display device DSP. In FIGS. 9A to 9J, the focus is primarily on the display area DA, and elements below the organic insulating layer 12 are omitted.

In forming the panel portion PP, first, a substrate 10 of the mother board MB is prepared, and a circuit layer 11 and an organic insulating layer 12 are formed thereon (processing step PR1 in FIG. 8). Next, as shown in FIG. 9A, lower electrodes LE1, LE2, and LE3 are formed on the organic insulating layer 12 (processing step PR2 in FIG. 8).

Next, as shown in FIG. 9B, a rib layer 5 covering the lower electrodes LE1, LE2, and LE3 is formed over the entire mother board MB (process step PR3 in FIG. 8). At this point, the pixel apertures AP1, AP2, and AP3 are not yet provided in the rib layer 5. The rib layer 5 can be formed by chemical vapor deposition (CVD).

After the formation of the rib layer 5, another processing step for forming the partition 6 is performed (processing step PR4 in FIG. 8). In the processing step PR4, as shown in FIG. 9C, the first layer L1 to be processed into the bottom layer 63, the second layer L2 to be processed into the axis layer 64, the third layer L3 to be processed into the first top layer 65, and the fourth layer L4 to be processed into the second top layer 66 are sequentially formed over the entire mother board MB. Further, the resist R1 is disposed on the fourth layer L4. The resist R1 is patterned into the shape of the partition 6. The first layer L1, second layer L2, third layer L3, and fourth layer L4 can be formed, for example, by sputtering.

Subsequently, with use of the resist R1 as a mask, the first layer L1, second layer L2, third layer L3, and fourth layer L4 are patterned. In one example, the first layer L1 is formed from titanium nitride, the second layer L2 is formed from aluminum, the third layer L3 is formed from titanium, and the fourth layer L4 is formed from ITO. In this case, the above-described patterning may include wet etching to remove the portions of the fourth layer L4, which are exposed from the resist R1, dry etching to remove the portions of the first layer L1, second layer L2, and third layer L3, which are exposed from the resist R1, and wet etching to reduce the width of the second layer L2.

After the processing step PR4, as shown in FIG. 9D, the partition 6 is formed in the display area DA. After the formation of the partition 6, the resist R1 is removed (peeled off). In the wet etching to reduce the width of the second layer L2 described above, the second top layer 66 (fourth layer L4) may also be slightly eroded. When this erosion occurs, the width of the second top layer 66 becomes less than the width of the first top layer 65.

Next, another processing step is performed to form the pixel apertures AP1, AP2, and AP3 (processing step PR5 in FIG. 8). In this processing step PR5, as shown in FIG. 9E, the resist R2 which covers the partition 6 is formed. Further, with use of the resist R2 as a mask, dry etching is performed on the rib layer 5. In this manner, the pixel apertures AP1, AP2, and AP3, which expose the lower electrodes LE1, LE2, and LE3, are formed in the rib layer 5, as shown in FIG. 9F. After the above-described dry etching, the resist R2 is removed (peeled off).

After the processing step PR5, another processing step is performed to remove the rib layer 5 in the inspection pads disposed in the margin area FA (processing step PR6 in FIG. 8). In the processing step PR6, an opened resist in the respective inspection pad is formed on the rib layer 5, and dry etching is performed on the rib layer 5.

After the processing step PR6, another processing step is performed to form the display element DE1 (processing step PR7 in FIG. 8). In forming the display element DE1, first, as shown in FIG. 9G, the stacked multilayer film FL1 and the sealing layer SE11 are formed. The stacked multilayer film FL1 includes an organic layer OR1 brought into contact with the lower electrode LE1 through the pixel aperture AP1, an upper electrode UE1 that covers the organic layer OR1, and a cap layer CP1 that covers the upper electrode UE1, as shown in FIG. 3. The organic layer OR1, the upper electrode UE1, and the cap layer CP1 can be formed, for example, by vapor deposition. On the other hand, the sealing layer SE11 can be formed, for example, by CVD.

The stacked multilayer film FL1 and the sealing layer SE11 are formed over the entire mother board MB, including not only the display area DA of each of the panel portions PP but also the peripheral area SA. The stacked multilayer film FL1 is divided into a plurality of parts by an overhanging partition 6. The sealing layer SE11 continuously covers the divided parts of the stacked multilayer film FL1 and the partition 6.

Next, the stacked multilayer film FL1 and the sealing layer SE11 are patterned. In this patterning process, as shown in FIG. 9G, the resist R3 is placed on the sealing layer SE11. The resist R3 covers the subpixel SP1 and parts of the partition 6 surrounding therearound.

Subsequently, an etching process is performed using the resist R3 as a mask. As a result, as shown in FIG. 9H, the portions of the stacked multilayer film FL1 and the sealing layer SE11, which are exposed from the resist R3 are removed. In other words, the portions of the stacked multilayer film FL1 and the sealing layer SE11, which overlap with the lower electrode LE1 are left to remain, while the other portions are removed. In this manner, the display element DE1 is formed in the subpixel SP1. For example, in the peripheral area SA, the stacked multilayer film FL1 and the sealing layer SE11 are removed by the etching process. The etching process may include wet etching and dry etching performed sequentially on the sealing layer SE11, the cap layer CP1, the upper electrode UE1, and the organic layer OR1. After these etching steps, the resist R3 is removed (peeled off).

After the processing step PR7, another processing step is performed to form the display element DE2 (processing step PR8 in FIG. 8). The display element DE2 can be formed by a procedure similar to that for the display element DE1. That is, when forming the display element DE2, the stacked multilayer film FL2 and the sealing layer SE12 are formed over the entire mother board MB. The stacked multilayer film FL2 includes an organic layer OR2 brought into contact with the lower electrode LE2 through the pixel aperture AP2, an upper electrode UE2 that covers the organic layer OR2, and a cap layer CP2 that covers the upper electrode UE2, as shown in FIG. 3.

The organic layer OR2, upper electrode UE2, and cap layer CP2 can be formed, for example, by vapor deposition. Further, the sealing layer SE12 can be formed, for example, by CVD. The stacked multilayer film FL2 is divided into a plurality of portions by the overhanging partition 6. The sealing layer SE12 continuously covers each of the divided portions of the stacked multilayer film FL2 and the partitions 6. By patterning the stacked multilayer film FL2 and the sealing layer SE2, the display element DE2 is formed in the respective subpixel SP2 as shown in FIG. 9I. For example, in the peripheral area SA, the stacked multilayer film FL2 and the sealing layer SE12 are removed by etching during the patterning process.

After the processing step PR8, another processing step is performed to form the display element DE3 (processing step PR9 in FIG. 8). The display element DE3 can be formed by a procedure similar to that for the display elements DE1 and DE2. That is, when forming the display element DE3, the stacked multilayer film FL3 and the sealing layer SE13 are formed over the entire mother board MB. The stacked multilayer film FL3 includes an organic layer OR3 brought into contact with the lower electrode LE3 through the pixel aperture AP3, an upper electrode UE3 that covers the organic layer OR3, and a cap layer CP3 that covers the upper electrode UE3, as shown in FIG. 3.

The organic layer OR3, upper electrode UE3, and cap layer CP3 can be formed, for example, by vapor deposition. Further, the sealing layer SE13 can be formed, for example, by CVD. The stacked multilayer film FL3 is divided into a plurality of portions by overhanging partition 6. The sealing layer SE13 continuously covers each of the divided portions of the stacked multilayer film FL3 and the partition 6. By patterning the stacked multilayer film FL3 and the sealing layer SE13, the display element DE3 is formed in the respective subpixel SP3, as shown in FIG. 9J. For example, in the peripheral area SA, parts of the stacked multilayer film FL3 and the sealing layer SE13 are removed by etching during the patterning process.

Note that, in the areas where the island-shaped portions IP are formed in the margin area FA, the stacked multilayer film FL3 and the sealing layer SE13 remain without being removed by etching. These remaining parts of the stacked multilayer film FL3 and sealing layer SE13 correspond to the stacked multilayer film FLx and the sealing layer SE1x shown in FIG. 6, respectively.

Note that here, the display elements DE1, DE2, and DE3 are assumed to be formed in this order, but the display elements DE1, DE2, and DE3 may be formed in some other order.

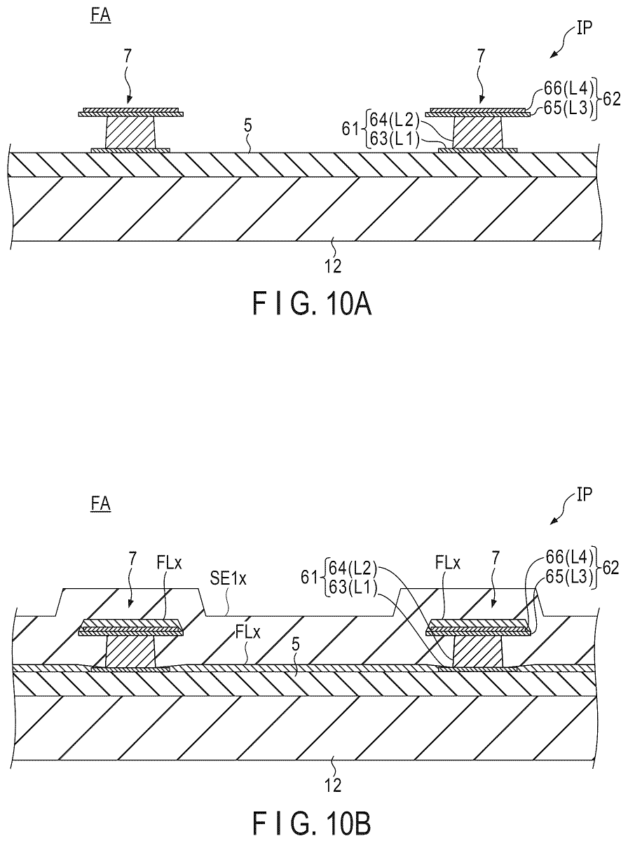

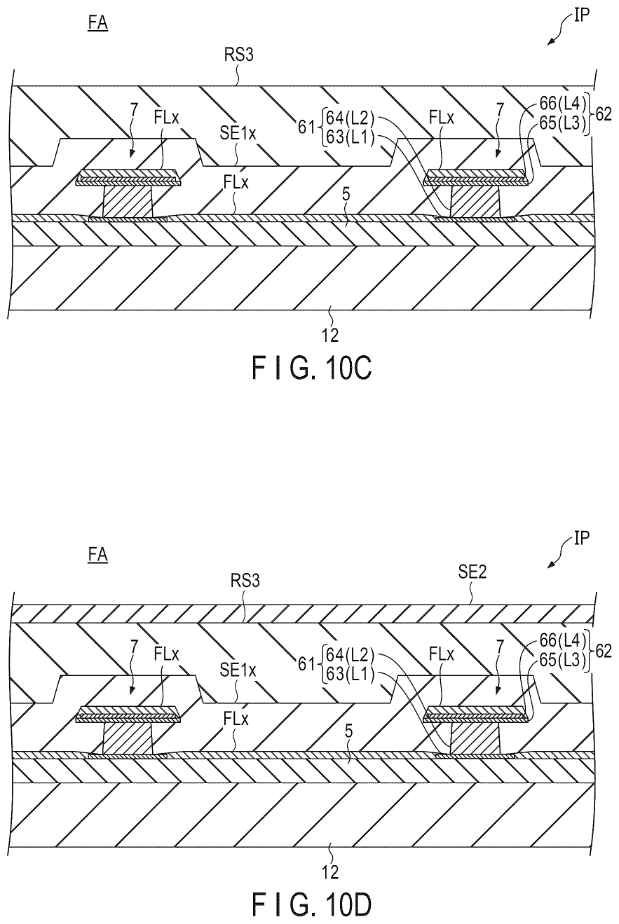

FIGS. 10A to 10D are schematic cross-sectional views showing the partition 7 of the island-shaped portion IP and the surrounding configuration in respective processing steps in the manufacturing of the display device DSP.

The partition 7 of the margin area FA is formed together with the partition 6 in the processing step PR4. After the processing step PR4, as shown in FIG. 10A, an overhanging partition 7 having a lower portion 61 and an upper portion 62 is formed. The bottom layer 63, axis layer 64, first top layer 65, and second top layer 66 of this partition 7 are processed from the first layer L1, second layer L2, third layer L3, and fourth layer L4 described above, respectively.

After the processing step PR9, as shown in FIG. 10B, a stacked multilayer film FLx and a sealing layer SE1x are formed in the island-shaped portion IP. The stacked multilayer film FLx is formed on the partition 7 and between each adjacent portions of the partition 7, as explained with reference to FIG. 7.

In other words, the stacked multilayer film FLx is finely divided by the partition 7. With this configuration, it is possible to suppress the divided portions of the stacked multilayer film FLx and the sealing layer SE1x covering these portions from peeling off from the substrate.

After the processing step PR9, another processing step is performed to form the resin layer RS1 (processing step PR10 in FIG. 8). The resin layer RS1 can be formed in an inner side of the dam structure DS (shown in FIG. 1) by, for example, an inkjet method. The dam structure DS serves to contain the resin layer RS1 of the state before it cures. The processing step PR10 includes a plurality of application steps (for example, three steps).

In the panel body PNLB, for example, the resin layer RS11 (shown in FIG. 6) is formed by the first application process, and then the resin layer RS12 (shown in FIG. 6) is formed on the resin layer RS11 by the second application process. Subsequently, by the third application process, the resin layer RS13 (shown in FIG. 6) is formed on the resin layer RS12. That is, the formation of the resin layer RS1 includes forming a plurality of layers.

Further, in the processing step PR10 of FIG. 8, as shown in FIG. 10C, the resin layer RS3 is formed on the sealing layer SE1x of the island-shaped portion IP. The resin layer RS3 is formed in the margin area FA (between the cut line CL1 and cut line CL2). Specifically, the resin layer RS3 is formed at each of the corner portions CN (shown in FIG. 5) of the cut line CL1.

For example, in the first application step of the processing step PR10, the resin layer RS3 is formed on the sealing layer SE1x of the island-shaped portion IP, together with the resin layer RS11, as shown in FIG. 10C. Further, in the second and third application steps of the processing step PR10, no resin layer is formed on the sealing layer SE1x of the island-shaped portion IP. As a result, the resin layer RS3 is formed thinner than the resin layer RS1. Specifically, the resin layer RS3 is formed by forming a less number of layers than that of the resin layer RS1.

As shown in FIG. 7, the resin layer RS3 is disposed on the sealing layer SE1x, and with this configuration, the resin layer RS3 is located at the end S1E of the sealing layer SE1x due to surface tension. Thus, the resin layer RS3 can be positioned at the intended location.

Here, an example is disclosed in which the resin layer RS3 of the island-shaped portion IP is formed simultaneously with the resin layer RS11 of the panel body PNLB. Note here that the resin layer RS3 of the island-shaped portion IP may be formed simultaneously with the resin layer RS12 of the panel body PNLB or simultaneously with the resin layer RS13 of the panel body PNLB.

After the processing step PR10, the sealing layer SE2 is formed over the entire mother board MB, for example, by CVD (processing step PR11 in FIG. 8).

After the processing step PR11, the resin layer RS1 of the panel body PNLB is covered by the sealing layer SE2.

Further, the sealing layer SE1x of the island-shaped portion IP and the resin layer RS3 are covered by the sealing layer SE2, as shown in FIGS. 7 and 10D. In the margin area FA, when the partition 7 is disposed in the area other than the island-shaped portion IP, the portions of the partition 7 is covered by the sealing layer SE2.

After the processing step PR11, another processing step is performed to remove the rib layer 5 and the sealing layer SE2 which cover the terminal portion T (processing step PR12 in FIG. 8). Further, another processing step is performed to remove the sealing layer SE2 surrounding the terminal portion T (processing step PR13 in FIG. 8).

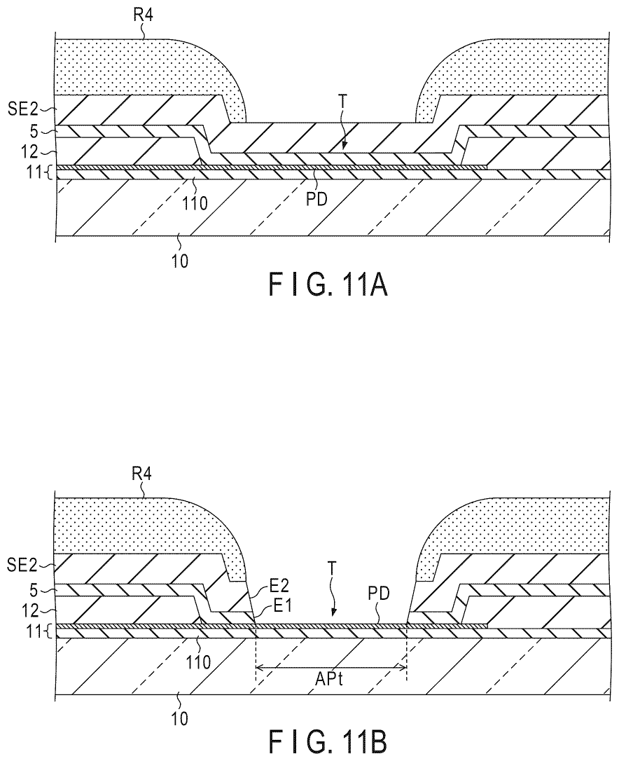

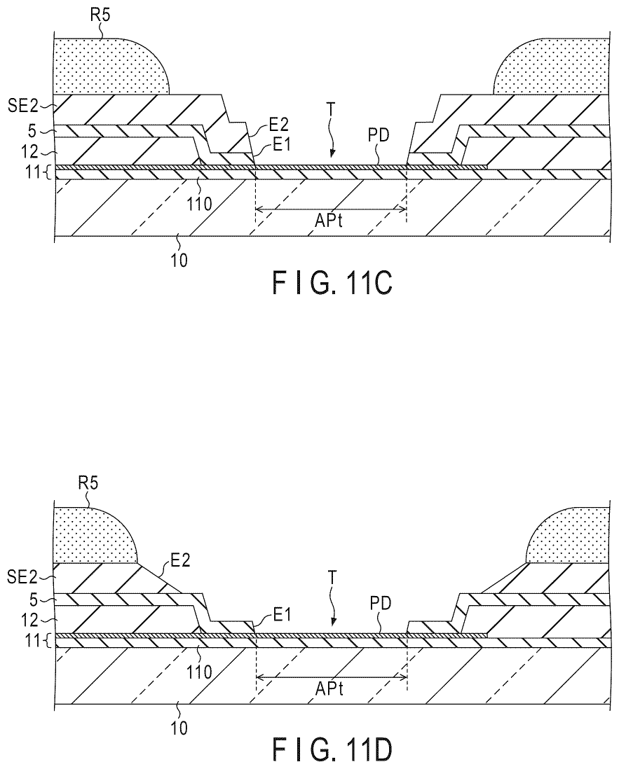

FIGS. 11A to 11D are schematic cross-sectional views of the terminal portion T, which illustrate the processing steps PR12 and PR13.

As shown in these figures, the terminal portion T includes a conductive pad PD. The pad PD is disposed on an insulating layer 110 formed, for example, of an inorganic insulating material. The pad PD and the insulating layer 110 are included in the circuit layer 11 shown in FIG. 3, for example. For example, the circumferential portion of the pad PD is covered by the organic insulating layer 12.

At the completion of the processing step PR11, as shown in FIG. 11A, the pad PD is covered by the rib layer 5 and the sealing layer SE2. In the processing step PR12, a resist R4 having such a shape that is opened above the pad PD is disposed on the sealing layer SE2. Further, with use of the resist R4 as a mask, dry etching is performed on the rib layer 5 and the sealing layer SE2.

As a result, as shown in FIG. 11B, an aperture APt which exposes the pad PD is formed in the rib layer 5 and sealing layer SE2. After the above-mentioned dry etching, the resist R4 is removed (peeled off). For example, in FIG. 11B, the edge E1 of the rib layer 5 surrounding the aperture APt and the edge E2 of the sealing layer SE2 surrounding the aperture APt are approximately aligned.

In the processing step PR13, as shown in FIG. 11C, a resist R5 having a shape that is opened larger than the aperture APt above the pad PD is disposed on the sealing layer SE2. Further, with use of the resist R5 as a mask, dry etching is performed on the sealing layer SE2. As a result, as shown in FIG. 11D, the edge E2 of the sealing layer SE2 retreats to be apart from the aperture APt. Further, the edge E2 becomes tapered with a gentle slope.

With such a shape of the edge E2 formed, it is possible to suppress connection defects of the flexible circuit board and the like to the terminal portion T, compared to the case where the edges E1 and E2 form steep walls as shown in FIG. 11C. After the dry etching of the sealing layer SE2, the resist R5 is removed (peeled off).

In the processing steps PR12 and PR13, contact apertures may be formed in the rib layer 5 and the sealing layer SE2 to connect the touch panel electrode TP (shown in FIG. 3) to the wiring lines of the circuit layer 11.

After the processing step PR13, the touch panel electrode TP is formed on the sealing layer SE2 (processing step PR14 in FIG. 8). Specifically, first, a conductive layer to be processed into the touch panel electrode TP is formed over the entire mother board MB. Next, a resist having a shape corresponding to that of the touch panel electrode TP is disposed, and the conductive layer is etched using this resist as a mask. After this etching, the resist is removed (peeled off).

After the processing step PR14, the resin layer RS2 is formed (processing step PR15 in FIG. 8). The resin layer RS2 can be formed on an inner side of the dam structure DS, for example, by an inkjet method. The dam structure DS serves to contain the resin layer RS2 of the state before it cures.

The resin layer RS2 may as well be formed by a photolithography process. In this case, first, a photosensitive resin to be processed into the resin layer RS2 is formed over the entire mother board MB. Then, through the processing steps of pre-baking, exposure, development, and baking of the photosensitive resin, the resin layer RS2 is formed in each of the panel portions PP.

After the processing step PR15, each panel portion PP is cut out from the mother board MB along the cut line CL1 (processing step PR16 in FIG. 8). Furthermore, the margin area FA is cut along the cut line CL2 (processing step PR17 in FIG. 8). Thus, the display panel PNL is completed in each respective part.

According to the above embodiment, it is possible to improve the yield of the display device DSP. Here, let us assume the case where the resist R5 is applied in the processing step PR13.

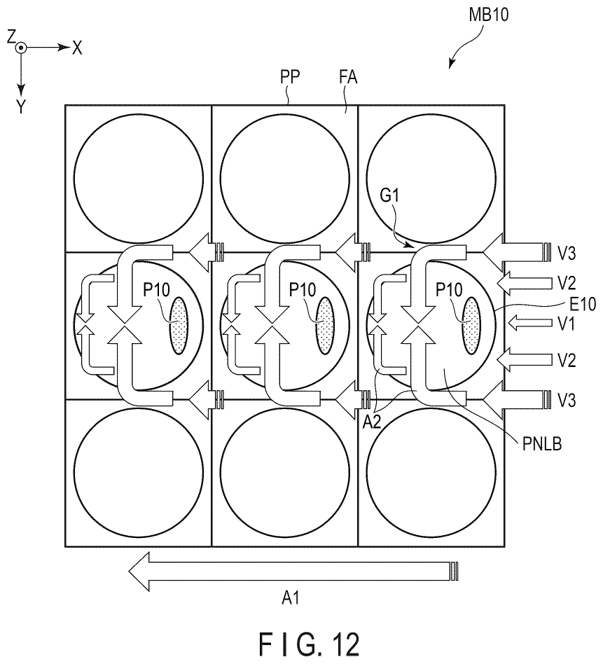

FIG. 12 is a schematic plan view of the mother board MB10 according to a comparative example with respect to the embodiment. The mother board MB10 according to the comparative example is differs from the mother board MB of the embodiment in that the island-shaped portions IP are not disposed in the margin area FA.

The resist R5 is applied in the direction of arrow A1 (opposite to the first direction X) in the example of FIG. 12. For example, the resist R5 is dripped from a nozzle (not shown) positioned above the mother board MB10, and the mother board MB10 is moved in the first direction X, thus applying the resist R5 over the entire surface of the mother board MB10.

Focusing on the panel portion PP located at the center of the right side in FIG. 12, the resist R5 dripped from the nozzle first collides with the end portion E10 of the panel body PNLB. The collided part of the resist R5 flows toward the panel body PNLB along the direction of arrow A1, while the remaining part flows toward the panel body PNLB while wrapping around the peripheral surface of the panel body PNLB from the outer side.

Further, between the panel bodies PNLB of each adjacent pair of panel portions PP, a gap G1 is formed. In the gap G1, no island-shaped section IP as of this embodiment is disposed. The resist R5 flowing through the gap G1 flows toward the panel body PNLB while a part thereof is wrapping around the gap G1 as indicated by the arrow A2.

In such a case, depending on the position along the second direction Y, a difference in speed (velocity) tends to occur in the resist R5 flowing through the panel portion PP. Specifically, as farther away from the central part of the panel body PNLB in the second direction Y, the flowing speed (velocity) of the resist R5 increases.

FIG. 12 shows the resist R5 flowing through the panel portion PP as arrows V1, V2, and V3 in order of increasing distance from the central part of the second direction Y of the panel body PNLB. The resist R5 flowing through the gap G1 corresponds to the arrow V3.

The sizes of these arrows V1, V2, and V3 indicate the speed (velocity) of the resist R5. The arrow V2 is larger than the arrow V1, and the arrow V3 is larger than the arrow V2. That is, the speed (velocity) of the resist R5 flowing through the central part of the panel body PNLB along the second direction Y is the slowest, and the speed (velocity) of the resist R5 flowing through the gap G1 is the fastest.

Thus, there is a significant difference in flow speed (velocity) between the resist R5 flowing through the central portion of the panel body PNLB along the second direction Y and the resist R5 flowing through the gap G1. Since the resist R5 flowing through the gap G1 has the highest velocity, it tends to be difficult to flow toward the end portion E10 of the panel body PNLB, as indicated by the arrow A2. As a result, a thin portion P10, which has a thickness less than the other parts of the resist R5, is formed on the side of the end portion E10. In FIG. 12, the thin portion P10 is marked with a dot pattern.

As described above, the resist R5 applied to the panel body PNLB is prone to application unevenness. Here, the term “application unevenness” refers to variations in the thickness of the resist R5. If application unevenness occurs in the resist R5, defects may arise in the display device DSP to be manufactured. Specifically, when the resist R5 is used as a mask, the thin portion P10 may not function sufficiently as a mask, which results in unnecessary removal of layers disposed below the resist R5. As a result, a decrease in the yield of the display device DSP can be caused.

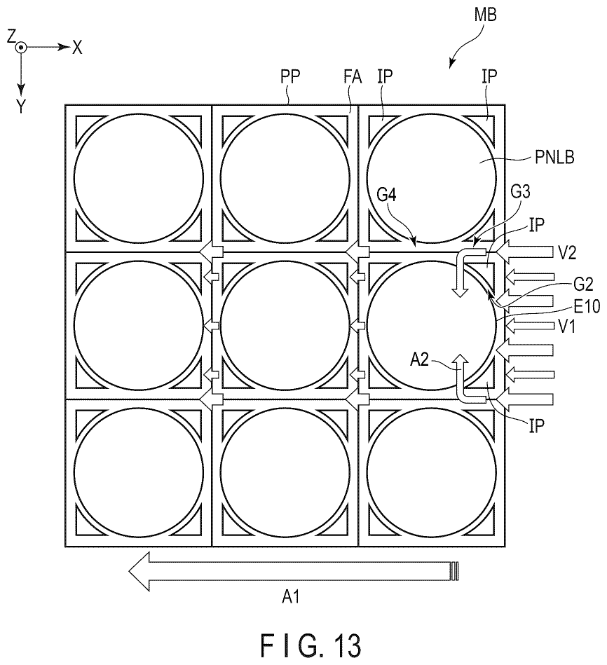

FIG. 13 is a schematic plan view of the mother board MB according to this embodiment. The resist R5 is applied in the direction of the arrow A1, as in the case of the example of FIG. 12. Here, focusing on the panel portion PP located at the center of the right side in FIG. 13, droplets of the resist R5 from the nozzle collide with the end portion E10 of the panel body PNLB.

In this embodiment, island-shaped portions IP are disposed respectively at the four corners of the panel portion PP. With this configuration, the resist R5 collides with these island-shaped portions IP (for example, the side surface including the edge M2 in FIG. 4) as well. The island-shaped portions IP have a function of colliding with the flowing resist R5 to reduce the velocity of the resist R5.

In such a case as described above, the difference in the velocity of the resist R5 depending on the position in the panel body PNLB along the second direction Y is smaller than that of the comparative example. Specifically, since the resist R5 collides not only with the end portion E10 but also with the island-shaped portions IP, it is not likely to create a great difference in the velocity of the resist R5 flowing in the central portion of the panel body PNLB along the second direction Y and in the vicinity of the island-shaped portion IP.

Further, by arranging the island-shaped portions IP at the respective four corners of the panel portion PP, the gap G1 shown in FIG. 12 is divided into the gap G2 between the panel body PNLB and the respective island-shaped portion IP (edge M3), the gap G3 between the respective island-shaped portions IP adjacent to each other, and the gap G4 between the respective panel bodies PNLB adjacent to each other. The gaps G2, G3, and G4 are smaller than the gap G1 in the comparative example.

With the above-described configuration, the speeds of the resist R5 flowing through the gaps G2, G3, and G4, respectively, decreases, and therefore it less likely to create differences in for speed to occur depending on the position of the resist R5 flowing in the panel body PNLB along the second direction Y.

A part of the resist R5 flowing through the gap G2 flows toward the panel body PNBL. The resist R5 flowing through the gap G3 progresses in the direction of arrow A1 along the edge M1 of the island-shaped portion IP, and a part thereof flows toward the panel body PNBL while wrapping around the island-shaped portion IP, as indicated by the arrow A2. Thus, it can be said that the island-shaped portion IP has a function of controlling the flow direction of the resist R5.

As described above, the island-shaped portions IP are disposed in the margin area FA so as to reduce the velocity difference of the flowing resist R5, and therefore the resist R5 flows more easily toward the panel body PNLB, thereby making it possible to suppress application unevenness of the resist R5 more effectively than in the comparative example.

In other words, by arranging the island-shaped portions IP, the formation of the thin portion P10 shown in FIG. 12 can be suppressed. As a result, the resist R5 functions reliably as a mask, and thus the removal of the layers below the resist R5 can be suppressed. Therefore, it is possible to reduce the defects in the display device DSP to be manufactured and improve the yield of the display device DSP.

In this embodiment, the island-shaped portion IP is arranged at each corner portion CN of the cut line CL1. With this configuration, it is possible to narrow the gap between the panel bodies PNLB of the panel portions PP adjacent to each other along the first direction X and the second direction Y, respectively. As a result, in each of the panel portions PP disposed on the mother board MB, the difference in the speed of the resist R5 being applied can be reduced, thereby suppressing application unevenness.

Further, in this embodiment, the island-shaped portion IP has the thickness of the resin layer, which is smaller than that of the panel body PNLB. For example, when sufficient space cannot be secured at the four corners of the panel portion PP, the size of the island-shaped portion IP may not be increased. But, even in such cases, by reducing the thickness of the resin layer RS3, the resin layer RS3 can be reliably disposed on the sealing layer SE1x. Note that the size of the island-shaped portion IP may be appropriately modified.

The suppression of the application unevenness of the resist by the island-shaped portion IP in this embodiment is not limited to the processing step PR13 shown in FIG. 8. For example, in processing steps performed after the processing step PR11, such as the processing steps PR12 and PR14 in FIG. 8, application unevenness can be suppressed by placing the island-shaped portions IP. For example, in the processing step PR14, by suppressing the application unevenness of the resist, touch panel electrodes TP of the desired shape can be obtained.

According to the manufacturing method for the mother board MB and the display device DSP configured as described above, it is possible to improve the yield. Further, various other advantageous effects can be obtained from this embodiment.

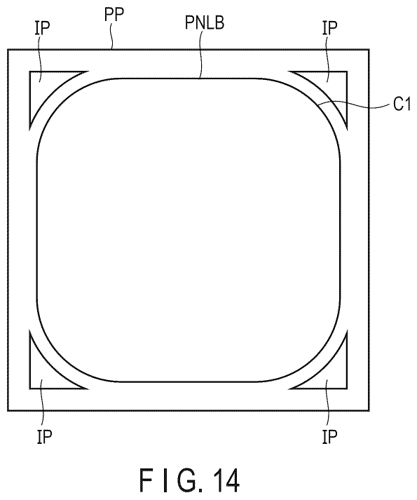

Note that the shape of the panel body PNLB (display panel PNL) is not limited to that of the above-provided example. FIG. 14 is a plan view showing an example of some other shape of the panel body PNLB.

The panel body PNLB may have a rectangular shape. The corners C1 of the panel body PNLB may have a rounded shape, as shown in FIG. 14. The radius of curvature of the corners C1 can be changed as appropriate.

Even in such a case, by arranging the island-shaped portions IP at the respective corner portions CN of the panel portion PP, the yield of the display device DSP can be improved. The shape of the island-shaped portions IP in the plan view is not limited to that of the example presented.

Further, this embodiment discloses an example in which the thickness of the resin layer RS3 is smaller than the thickness of the resin layer RS1, but the thickness of the resin layer RS3 may have a thickness equivalent to that of the resin layer RS1.

For example, the thickness of the resin layer RS3 can be increased by increasing the application process in the island-shaped portions IP during the processing step PR10 of FIG. 8.

Based on the display devices, the mother boards and the manufacturing methods described above as embodiments of the invention, a person having ordinary skill in the art may achieve display devices, mother boards and manufacturing devices with arbitral design changes; however, as long as they fall within the scope and spirit of the present invention, all of such display devices are encompassed by the scope of the present invention.

A skilled person would conceive various changes and modifications of the present invention within the scope of the technical concept of the invention, and naturally, such changes and modifications are encompassed by the scope of the present invention. For example, if a skilled person adds/deletes/alters a structural element or design to/from/in the above-described embodiments, or adds/deletes/alters a step or a condition to/from/in the above-described embodiment, as long as they fall within the scope and spirit of the present invention, such addition, deletion, and altercation are encompassed by the scope of the present invention.

Furthermore, regarding the present embodiments, any advantage and effect those will be obvious from the description of the specification or arbitrarily conceived by a skilled person are naturally considered achievable by the present invention.

What is claimed is

1. A mother board for a display device, comprising:
a display area for displaying an image;
a margin area on an outer side of a cut line for cutting out the display area;
an inorganic insulating layer disposed in the display area and the margin area;
a display element disposed in the display area;
a first partition disposed above the inorganic insulating layer in the margin area;
a first sealing layer formed of an inorganic insulating material and disposed above the display element and the first partition; and
a first resin layer disposed above the first sealing layer in the margin area.

2. The mother board of claim 1, wherein
the first partition includes
a first lower portion disposed on the inorganic insulating layer, and
a first upper portion disposed on the first lower portion and protruding from a side surface of the first lower portion.

3. The mother board of claim 1, further comprising:
a second resin layer disposed on the first sealing layer in the display area,
wherein
the first resin layer has a thickness smaller than that of the second resin layer.

4. The mother board of claim 3, further comprising:
a second sealing layer formed of an inorganic insulating material and covering the first resin layer and the second resin layer.

5. The mother board of claim 3, wherein
the first resin layer is formed from a single layer, and
the second resin layer is formed from a plurality of layers.

6. The mother board of claim 3, wherein
the first resin layer is separated from the second resin layer.

7. The mother board of claim 1, further comprising:
a second partition disposed in the display area and surrounding the display element,
wherein
the second partition includes
a second lower portion disposed on the inorganic insulating layer, and
a second upper portion disposed on the second lower portion and protruding from a side surface of the second lower portion.

8. The mother board of claim 1, further comprising:
a stacked multilayer film including an organic layer and an upper electrode contained within the display element,
wherein
the stacked multilayer film is disposed between the first partition and the first sealing layer in the margin area.

9. The mother board of claim 8, wherein
the stacked multilayer film is disposed between adjacent portions of the first partition.

10. The mother board of claim 9, wherein
the stacked multilayer film further includes a cap layer disposed on the upper electrode, and
the cap layer is disposed in the margin area as well.

11. A mother board for a display device, comprising:
a display area which displays images;
a margin area on an outer side of a first cut line for cutting out the display area;
a display element disposed in the display area;
a first partition arranged in the margin area;
a first sealing layer formed of an inorganic insulating material and disposed above the display element and the first partition;
a first resin layer disposed on the first sealing layer in the margin area; and
a second resin layer disposed on the first sealing layer in the display area,
wherein
the margin area includes a plurality of island-shaped portions including the first partition, the first sealing layer, and the first resin layer, and
the plurality of island-shaped portions are each disposed, in plan view, to be separated from the second resin layer around the first cut line.

12. The mother board of claim 11, wherein
the plurality of island-shaped portions are each disposed between the first cut line and a second cut line for cutting out the display area and the margin area.

13. The mother board of claim 12, wherein
the first cut line is formed into a circular shape, and
the second cut line is formed into a quadrangular shape.

14. The mother board of claim 13, wherein
the plurality of island-shaped portions are disposed at corner portions of the second cut line, respectively.

15. A method of manufacturing a display device, comprising:
preparing a substrate including a display area which displays images and a margin area on an outer side of a first cut line for cutting out the display area;
forming an inorganic insulating layer on the display area and the margin area;
forming a first partition including a lower portion and an upper portion including an end portion protruding from a side surface of the lower portion, on the inorganic insulating layer in the margin area;
forming a display element in the display area;
forming a first sealing layer above the display element and the first partition; and
forming a first resin layer on the first sealing layer in the margin area.

16. The method of claim 15, further comprising:
forming a second sealing layer of an inorganic insulating material, which covers the first resin layer.

17. The method of claim 15, further comprising:
forming a second resin layer disposed on the first sealing layer in the display area,
wherein
the forming the first resin layer includes forming the first resin layer to be thinner than the second resin layer.

18. The method of claim 17, wherein
the forming the second resin layer includes forming a plurality of layers, and
the forming the first resin layer includes forming a less number of layers than that of the second resin layer.

19. The method of claim 17, further comprising:
cutting out the display area and the margin area from the substrate along the second cut line; and
cutting out the display area along the first cut line,
wherein
the forming the first resin layer includes forming the first resin layer between the first cut line and the second cut line.

20. The method of claim 19, wherein
the first cut line is formed into a circular shape,
the second cut line is formed into a quadrangular shape, and
the forming the first resin layer includes forming the first resin layer at a corner portion of the second cut line.
